(19) United States
(12) Patent Application Publication
(10) Pub. No.: US 2005/0167785 A1
(43) Pub. Date: Aug. 4, 2005

(54) Semiconductor device and manufacturing method thereof

(75) Inventors: Hisaaki Tominaga, Ora-gun (JP); Keita Odajima, Fukaya-city (JP); Shigehito Matsumoto, Kumagaya-city (JP); Masamichi Yamamuro, Ashikaga-city (JP)

Correspondence Address: Barry E. Bretchneider;Morrison & Foerster LLP, Suite 300, 1650 Tysons Boulevard, McLean, VA, 22102, US

(73) Assignee: Sanyo Electric Co., Ltd., Moriguchi-city (JP)

(21) Appl. No.: 11/024,225

(22) Filed: Dec. 29, 2004

(30) Foreign Application Priority Data
Jan. 30, 2004 (JP) 2004-022817

(51) Int. Cl. H01L 29/00

(52) U.S. Cl. 257/565

(57) ABSTRACT

In a bipolar transistor, an SIC layer is provided right under a genuine base region in order to suppress the Kirk effect and improve fT characteristic by thinning the film of the genuine base region. The higher the concentration of impurities in the SIC layer, the bigger the effect. When the impurity concentration of the SIC layer is high, the VCEO deteriorates so that the fT characteristic improvement and the Kirk effect suppression are in a trade off relationship with the VCEO. A second SIC layer is provided right under the genuine base region and in contact therewith, and a first SIC layer with a higher impurity concentration than the second SIC layer is formed right under the second SIC layer. The first SIC layer narrows the collector width and suppresses the Kirk effect whereas, the second SIC layer makes it possible to improve fT characteristic by cutting a lower edge of the genuine base region. Two SIC layers having varying depths can be formed in one heat treatment by using in the first SIC layer impurities that have a larger diffusion coefficient than the impurities of the second SIC layer.

### BACKGROUND OF THE INVENTION

1. Field of the Invention

The present invention relates to a semiconductor device and a manufacturing method thereof, more in particular to a semiconductor device having a reduced base region width and an improved impurity concentration of a collector region, and a manufacturing method thereof.

2. Description of the Related Art

Conventionally, compound semiconductor devices were used in high frequency circuits using a GHz band. However, because compound semiconductor devices use diverse manufacturing processes and technologies, they are very expensive so that recently effort has been made to develop a silicon semiconductor device which is mass productive and which can be manufactured using existent production lines. A description is next given of a semiconductor device of such a high frequency application using as an example of an npn bipolar transistor.

FIG. 12 shows a cross sectional view of a conventional npn type bipolar transistor. The bipolar transistor is provided with an n⁺ type semiconductor substrate 31 and a collector region 32 formed by laminating an n⁻ type epitaxial layer on the substrate 31.

Further, after a LOCOS(Local Oxidation of Silicon) oxide film 34 is provided, an outside base region 39 and a genuine base region 41 are formed on a surface of the semiconductor substrate between two portions of the LOCOS oxide film 34.

A plurality of outside base regions 39 and genuine base regions 41 are preferably provided, for instance in a comb tooth-like shape and an emitter region 46 is provided on a surface of each genuine base region 41, respectively. A base extraction electrode 37 and an emitter extraction electrode 45 made of a conductive material functioning as an impurity diffusion source for forming respective regions are provided in contact with the outside base region 39 and the emitter region 46. Further, a base electrode 48 connected to the base extraction electrode 37 and an emitter electrode 49 connected to the emitter extraction electrode 45 respectively, are then formed. Also, a collector electrode (not illustrated here) electrically connected to the collector region 32 is formed. This figure shows a single-layer electrode structure, but a two-layer metal structure can also be employed. This technology is described for instance in Japanese Laid-Open 2001-358152 (page 3, FIG. 1) A manufacturing method of a conventional bipolar transistor is next described with reference to FIG. 12 thru FIG. 14.

First, a collector region 32 is formed by laminating an n⁻ type epitaxial layer on an n⁺ type silicon substrate 31. After providing a mask which creates an opening in a predetermined region, a LOCOS oxide film 34 is formed.

In the next step, a polysilicon layer 35 is deposited on the entire surface and p type impurities are ion implanted. An acceleration energy at this time is equal to or less than 40 KeV and an ion implantation dose is about 5E15 cm⁻². Next, an insulating film such as a TEOS (Tetra Ethyl Ortho Silicate) film 36 or the like is also deposited (See FIG. 13A).

Next, since an opening is formed at a predetermined emitter region portion and the polysilicon layer 35 is patterned in a predetermined shape, a mask made of a resist is provided so as to then form an opening OP by etching and removing the exposed polysilicon layer 35 and TEOS film 36. A base extraction electrode 37 also functioning as a base diffusion source is thus formed thereby. Then, an insulating film 40 is formed in the opening OP in order to protect a surface of the genuine base region and p type impurities are ion implanted in the opening OP. (See FIG. 13B)

Next, heat treatment is carried out for a short period of time by an RTA (Rapid Thermal Anneal) method to form a genuine base region 41. Also, p type impurities of the base diffusion source 37 are diffused on a surface of the collector region 32 in the same heat treatment process. As described hereinabove, the base diffusion source 37 is doped with p type impurities in order to form an outside base region 39 which is in contact with the genuine base region 41 in a vicinity of a surface thereof. (See FIG. 13C)

Next, a non-doped polysilicon layer is deposited on the entire surface after which etching is carried out so that a sidewall 43 is formed on inner walls of the opening OP. The side wall 43 is used to secure the distance between the outside base region 39 and an emitter region to be formed in a subsequent process by self alignment. (FIG. 14A)

Next, an emitter region is formed on a surface of the genuine base region 41 by removing the insulating film 40 deposited on the genuine base region 41 in a wet etching process and forming an emitter contact EC having the genuine base region 41 exposed therefrom.

Further, a polysilicon layer is provided on the entire surface and n type impurities are doped therein. The polysilicon layer is then patterned and the opening OP section and a section having a predetermined shape necessary for wiring are left to thus form an emitter extraction electrode 45 which functions as an emitter diffusion source. A part of the emitter extraction electrode 45 is also left on the TEOS film 36 at a periphery of the opening OP.

Then, n type impurities are diffused on a surface of the genuine base region 41 from the emitter diffusion source 45 so as to form an emitter region 46. Thus by forming the emitter region 46, a predetermined base width Wb is provided. (FIG. 14B)

After an insulating film 47 is formed for planarization purposes, a through hole TH is provided in the TEOS film 36 and in the insulating film 47 deposited on the LOCOS oxide film 34 and another through hole TH is formed in the insulating film 47 deposited on the emitter extraction electrode 45. After that, a metal layer is deposited and after patterning in a desired shape, a base electrode 48 contacting the base extraction electrode 37 is formed. Also, an emitter electrode 49 contacting the emitter extraction electrode 45 is further provided. The final structure as shown in FIG. 12 is obtained by forming a collector electrode (not illustrated here) which is electrically connected to the collector region.

One of the indexes showing the characteristics of a bipolar transistor is the fT (gain-bandwidth product). The fT characteristic can be improved by thinning the layer of the genuine base region 41 and thinning the collector region 32.

When the collector current density is high, the space charge inside a depletion layer of the collector region 32 is negated by the space charge which electrons make and a phenomenon (Kirk effect) occurs according to which the width of the genuine base region expands substantially, leading to a deterioration in current amplification (hFE) and in fT characteristic.

The Kirk effect can be suppressed by increasing the impurity concentration of the collector region 32 right below the genuine base region 41.

A SIC (Selectively Ion Implanted Collector) layer which forms an impurity layer of an opposite conductivity type from the base layer right below the genuine base region 41 is known, as shown in FIG. 15, for the abovementioned purposes.

The impurity layer (the SIC layer 55) formed by the SIC can make the genuine base region 41 thinner and can locally increase the impurity concentration of the collector region 32 provided right below the genuine base region carrying out the bipolar transistor operation.

Here, the higher the concentration of the impurities of the SIC layer 55 provided right below the genuine base region 41, the better the Kirk effect can be suppressed. However, when the concentration of the impurities in the SIC layer 55 is increased, a deterioration occurs in the breakdown voltage (shown by VCEO hereinafter) between the collector and emitter. The VCEO is generally dependent on the impurity concentration of the whole collector region 32, but, if, due to the formation of the SIC layer 55, the impurity concentration right under the genuine base region 41 carrying out operation of the bipolar transistor is high, the breakdown voltage is determined by impurity concentration of the SIC layer 55.

In order to avoid the deterioration in the VCEO, the genuine base region 41 cannot be thinned and the Kirk effect cannot be suppressed by reducing the impurity concentration of the SIC layer 55. Accordingly, the impurity concentration of the SIC layer 55 and the VCEO are in a trade-off relationship, and the main issue here is forming an efficient SIC layer 55 without reducing the VCEO.

### SUMMARY OF THE INVENTION

The present invention is made in view of the above problems, and a main aspect thereof is to provide a semiconductor device comprising a one conductivity type collector region provided on a surface of a semiconductor device; an opposite conductivity type base region provided on a surface of the collector region and a one conductivity type emitter region provided on a surface of the base region, wherein a first one conductivity type impurity layer and a second one conductivity type impurity layer are formed in the collector region at a lower portion of the base region.

Another aspect of the invention is that the base region comprises a genuine base region and an outside base region contacting both ends of the genuine base region, wherein the first and the second one conductivity type impurity layers are provided right below the genuine base region.

A further aspect of the invention is to provide the second one conductivity type impurity layer between the base region and the first one conductivity type impurity layer.

Another aspect of the invention is that the first one conductivity type impurity layer has a higher impurity concentration than the second one conductivity type impurity layer.

A further aspect of the invention is that the first one conductivity type impurity layer has a higher impurity concentration than the collector region.

According to some embodiments of the invention, the impurities of the first one conductivity type impurity layer have a larger diffusion coefficient than the impurities of the second one conductivity type impurity layer.

According to some embodiments of the invention, a groove is provided between outside base regions, sidewalls thereof contacting a vicinity of a surface of the outside base regions and wherein the genuine base region is formed on a surface of the collector region at a bottom of the groove.

Secondly, a yet further aspect of the present invention is to provide a manufacturing method of a semiconductor device comprising forming a one conductivity type collector region on a semiconductor substrate; forming an opposite conductivity type base region on a surface of the collector region and forming a first one conductivity type impurity layer and a second one conductivity type impurity layer at a lower portion of the base region; forming a one conductivity type emitter region in the base region.

Thirdly, another aspect of the invention is to provide a manufacturing method of a semiconductor device comprising forming a one conductivity type collector region on a semiconductor substrate; forming an opposite conductivity type outside base region on a surface of the collector region; ion implanting first one conductivity type impurities, second one conductivity type impurities and opposite conductivity type impurities between outside base regions; forming an opposite conductivity type genuine base region by heat treatment, a first one conductivity type impurity layer at a lower portion of the genuine base region and a second one conductivity type impurity layer between the genuine base region and the first one conductivity type impurity layer; and forming a one conductivity type emitter region in the genuine base region.

A further aspect of the invention is that the first one conductivity type impurity layer has a higher impurity concentration than the second one conductivity type impurity layer.

A yet further aspect of the invention is that the first one conductivity type impurity layer has a higher impurity concentration than the collector region.

Another aspect of the invention is that the genuine base region, the first one conductivity type impurity layer and the second one conductivity type impurity layer are formed simultaneously in one heat treatment by implanting impurities having a varying diffusion coefficient.

Another aspect of the invention is that after forming a groove in the collector region, the outside base regions are formed on both sides of the groove.

According to embodiments of this invention, firstly, the Kirk effect can be suppressed by providing a first SIC layer having an impurity concentration about 1E18 cm⁻³ at a deep position thereof, reducing resistance of the collector region and increasing the space charge density between the base and the collector.

Secondly, a second SIC layer is provided right below the genuine base region and at a shallower position than the first SIC layer and by cutting smooth portions of the impurity concentration profile at a lower end of the genuine base region, the width (Wb) of the genuine base region can be reduced and the fT characteristic can be improved.

Thirdly, the large deterioration in the VCEO which was a point of concern by providing the SIC layer in the conventional device can be suppressed by setting the impurity concentration of the second SIC layer to about 1E17 cm⁻³, which means an impurity concentration lower than that of the first SIC layer.

Fourthly, the width (Wb) of the genuine base region can be reduced due to the fact that the second SIC layer can comprise arsenic ions having a small diffusion coefficient.

Accordingly, high frequency characteristics can be improved without any deteriorate in the VCEO by providing, right under the genuine base region, two types of SIC layers having different depths and impurity concentrations.

### BRIEF DESCRIPTION OF THE DRAWINGS

FIG. 1A is a plan view and FIG. 1B is a cross-sectional view showing a semiconductor device according to some embodiments of the invention.

FIG. 2 is a characteristics view showing a semiconductor device according to some embodiments of the invention.

FIG. 3 is a cross-sectional view showing a manufacturing method of a semiconductor device according to some embodiments of the invention.

FIG. 4 is a cross-sectional view showing a manufacturing method of a semiconductor device according to some embodiments of the invention.

FIG. 5 is a cross-sectional view showing a manufacturing method of a semiconductor device according to some embodiments of the invention.

FIG. 6 is a cross-sectional view showing a manufacturing method of a semiconductor device according to some embodiments of the invention.

FIG. 7 is a cross-sectional view showing a semiconductor device according to some embodiments of the invention.

FIG. 8 is a cross-sectional view showing a manufacturing method of a semiconductor device according to some embodiments of the invention.

FIG. 9 is a cross-sectional view showing a manufacturing method of a semiconductor device according to some embodiments of the invention.

FIG. 10 is a cross-sectional view showing a manufacturing method of a semiconductor device according to some embodiments of the invention.

FIG. 11 is a cross-sectional view showing a manufacturing method of a semiconductor device according to some embodiments of the invention.

FIG. 12 is a cross-sectional view showing a conventional semiconductor device.

FIG. 13 is a cross-sectional view showing a manufacturing method of a conventional semiconductor device.

FIG. 14 is a cross-sectional view showing a manufacturing method of a conventional semiconductor device.

FIG. 15 is a cross-sectional view showing a manufacturing method of a conventional semiconductor device.

### DETAILED DESCRIPTION OF THE INVENTION

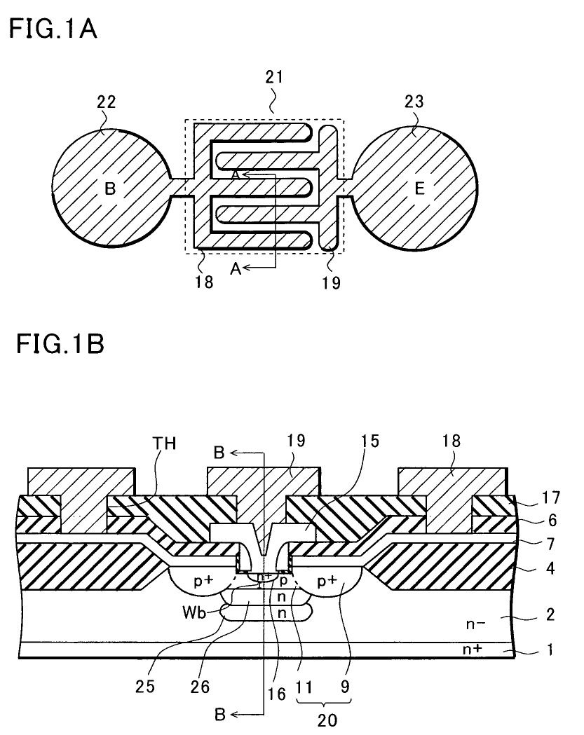

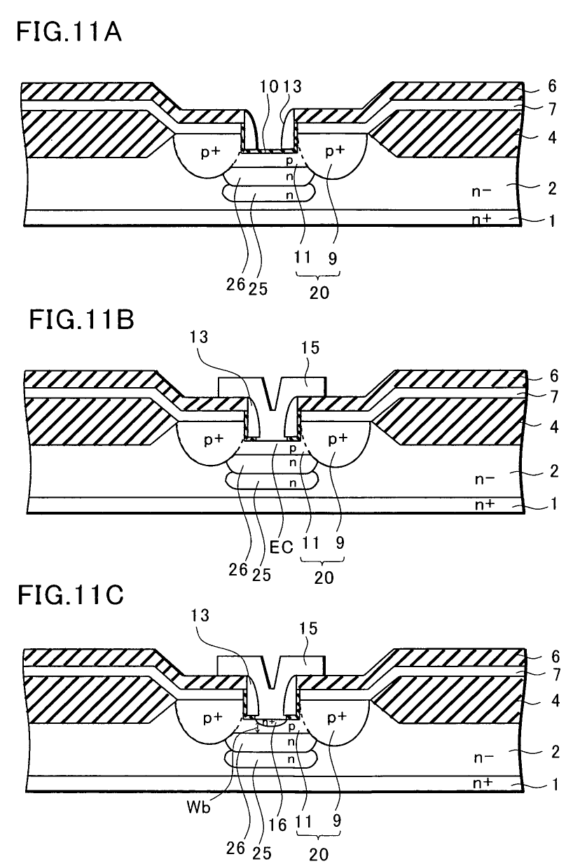

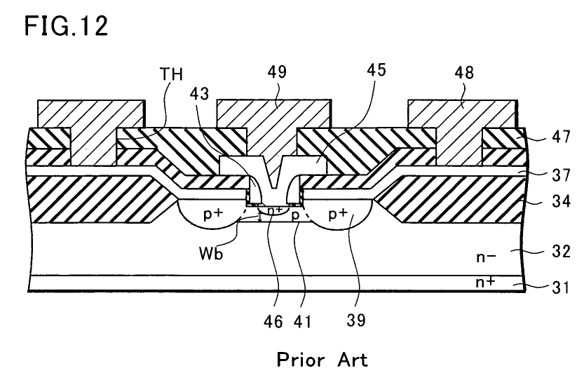

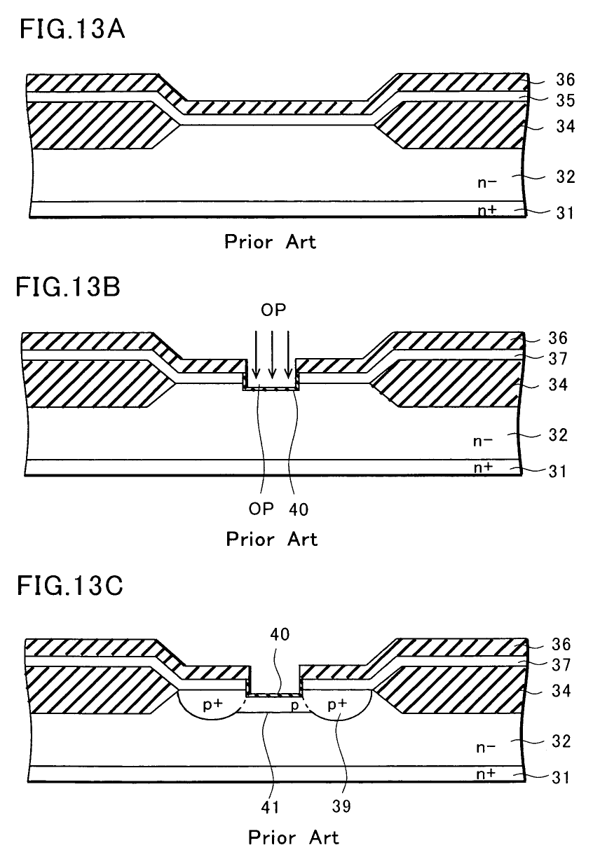

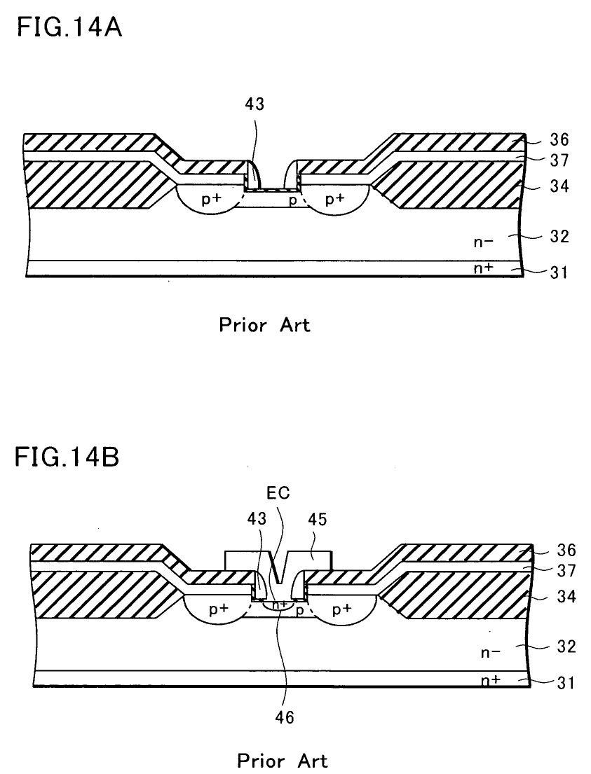

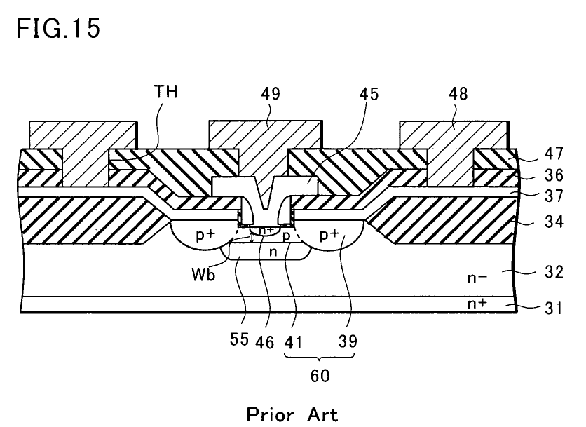

Embodiments of the present invention are described with reference to FIG. 1 thru FIG. 11, using an npn type bipolar transistor.

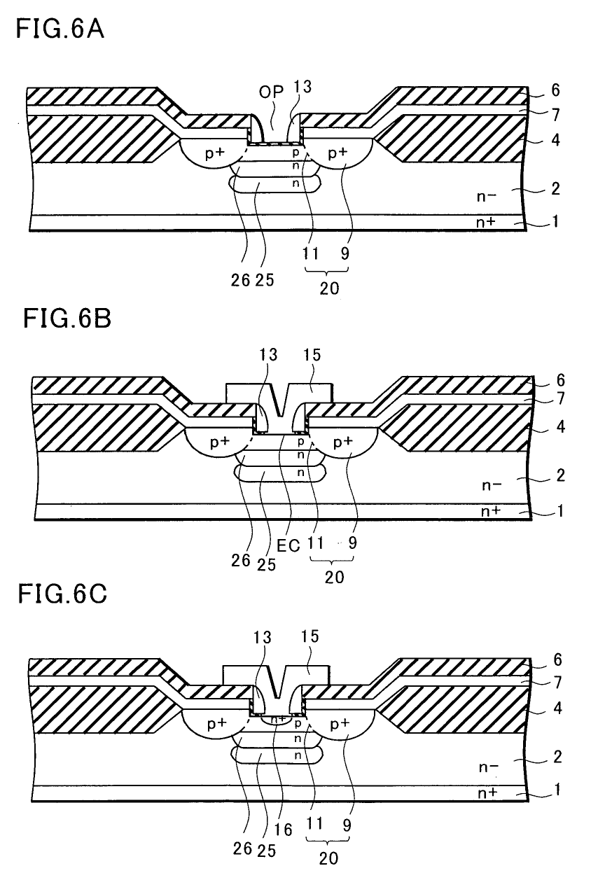

First, a first embodiment is described with reference to FIG. 1 thru FIG. 6. FIG. 1 shows a plan view and a cross-sectional view of a bipolar transistor according to the present embodiment. FIG. 1B is a cross-sectional view taken along line A-A of FIG. 1A.

The bipolar transistor according to this embodiment comprises a semiconductor substrate 1, a collector region 2, an outside base region 9, a genuine base region 11, an emitter region 16, a base extraction electrode 7, an emitter extraction electrode 15, a base electrode 18, an emitter electrode 19, a first one conductivity type impurity layer 25 and a second one conductivity type impurity layer 26.

Abase region and an emitter region (both of them not illustrated here) which function as diffusion regions are provided in a comb tooth-like shape in an operation region 21, and a base electrode 18 and an emitter electrode 19 contacting the base region and the emitter region, respectively, are aligned in a shape of engaged comb teeth, as shown in FIG. 1A. The base electrode 18 extends outside the operation region 21 to thus come in contact with a base pad electrode 22. Also, the emitter electrode 19 extends outside the operation region 21 to come in contact with an emitter pad electrode 23.

As shown in FIG. 1B, a semiconductor substrate 1 is an n⁺ type silicon substrate and a collector region 2 is formed by laminating, for example, an n⁻ type epitaxial layer thereon. A LOCOS oxide film 4 is provided at predetermined intervals on a surface of the collector region 2. A base region 20 comprising an outside base region 9 and a genuine base region 11 is formed on a surface of the collector region 2 between the LOCOS oxide film 4 in a comb tooth-like shape, for instance.

A first one conductivity type impurity layer 25 and a second one conductivity type impurity layer 26 can be formed by impurity diffusion at a lower portion of the genuine base region 11. Here, a first SIC layer 25 and a second SIC layer 26 are formed by SIC. The first SIC layer 25 preferably comprises phosphorus (P) which is suited for forming the first SIC layer 25 at a deep position because phosphorus ion has a small mass and a large Rp (projected range distance) during ion implantation.

On the other hand, the second SIC layer 26 preferably comprises arsenic (As) and is formed by impurities having a smaller diffusion coefficient than the first SIC layer 25. The reason why impurities having a smaller diffusion coefficient are used here is that the purpose of the second SIC layer 26 is to cut smooth portions of the impurity concentration profile at a lower end of the genuine base region, whereas in case impurities (for instance phosphorus) having a large diffusion coefficient are used, the impurity concentration profile itself of the genuine base region is influenced. The second SIC layer 26 is provided between and is in contact with the first SIC layer 25 and the genuine base region 11.

Emitter regions 16 are provided on surfaces of the genuine base regions 11 respectively. In more detail, a plurality of base regions 20 and emitter regions 16 are provided in a comb tooth-like shape and function as the operation region 21, thus forming the bipolar transistor.

The outside base region 9 is a p+ type impurity diffusion region provided on a surface of the collector region 2 and is in contact with the genuine base region 11.

A base extraction electrode 7 is in contact with the outside base region 9 and it is provided on the LOCOS oxide film 4. The base extraction electrode 7 comprises a conductive material such as polysilicon which includes impurities and also functions as a base diffusion source for forming the outside base region 9. It also contacts the base electrode 18 on the LOCOS oxide film 4 via a through hole TH provided in a TEOS film 6 and an insulating film 17.

An emitter extraction electrode 15 comprises a conductive material such as polysilicon, also including n type impurities and covers the inside of the opening OP. The emitter extraction electrode 15 functions as an emitter diffusion source forming an emitter region 16 and contacts the emitter region 16.

The base electrode 18 is connected to the outside base region 9 and the genuine base region 11 via the base extraction electrode 7. Also, the emitter electrode 19 is connected to the emitter region 16 via an emitter extraction electrode 15.

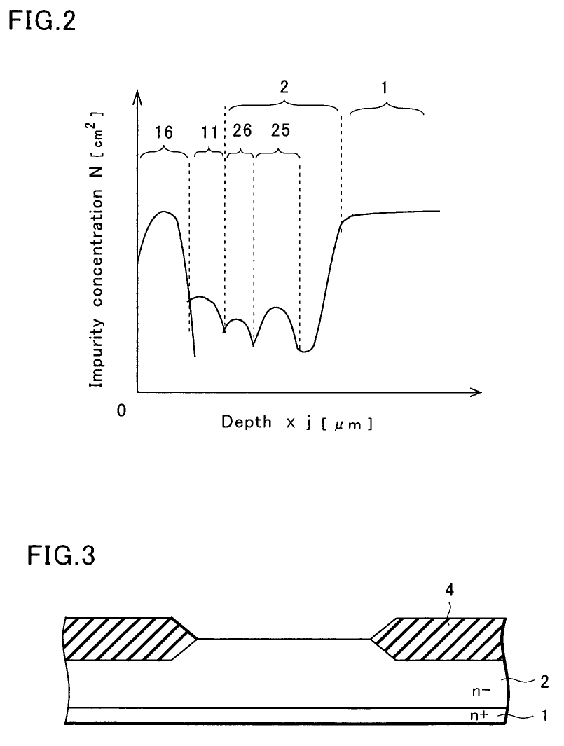

FIG. 2 shows the impurity concentration profile according to a cross-sectional view along the line B-B of FIG. 1B, according to a first embodiment of the invention.

FIG. 2 illustrates a impurity concentration profile of the emitter region 16, the genuine base region 11, the second SIC layer 26, the first SIC layer 25, the collector region 2 and the semiconductor substrate 1, in a depth direction from the substrate surface (Xj=0)

The first SIC layer 25 comprises phosphorus (P) impurities and is formed at a depth of about 0.4 um to 0.5 um from the substrate surface. The impurity concentration is about 1E18 cm⁻³, which is higher than that of the second SIC layer 26. By forming the first SIC layer 25 at a deep position from the substrate surface, the width of the collector region 2 having a low impurity concentration narrows and the Kirk effect can be suppressed by increasing the density of the space charge between the base and the collector.

The second SIC layer 26 comprises arsenic (As) impurities and is formed at a depth of about 0.2 from the substrate surface. The impurity concentration is about 1E17 cm⁻³, which is lower than that of the first SIC layer 25. Even if the second SIC layer 26 is formed to be in contact with the genuine base region 11 so as to cut a lower edge of the genuine base region 11, it does not influence in any way the impurity concentration profile of the genuine base region 11 because the diffusion coefficient is small and the genuine base region 11 having a predetermined width can be obtained.

According to this embodiment, the fT characteristic can be improved by positioning the second SIC layer 26 right below the genuine base region 11, and the Kirk effect can be suppressed by positioning the first SIC layer 25 at a deeper position from the substrate surface.

By increasing the impurity concentration of the SIC layer, the impurity concentration right below the genuine base region 11 carrying out the bipolar transistor operation influences the deterioration of the VCEO, however, with this embodiment, due to the existence of the second SIC layer 26 having a relatively low impurity concentration, it is possible to suppress a large deterioration in the VCEO.

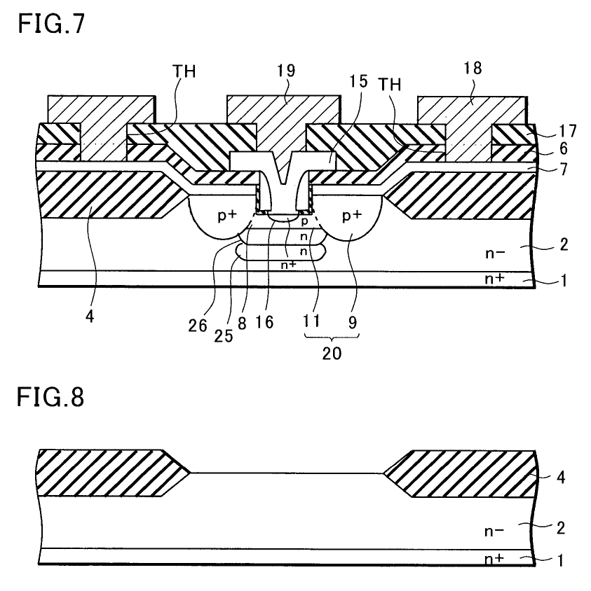

Next, a manufacturing method of a bipolar transistor according to the present embodiment of the invention is described with reference to FIG. 3 thru FIG. 7 and FIG. 1.

A manufacturing method of a bipolar transistor comprises forming a one conductivity type collector region on a semiconductor surface, forming an opposite conductivity type base region on a surface of the collector region, a first one conductivity type impurity layer and a second one conductivity type impurity layer at a lower portion of the base region; and forming a one conductivity type emitter region in the base region.

A first process of forming a one conductivity type collector region 2 on a semiconductor substrate 1 is described hereinafter with reference to FIG. 3.

A collector region 2 is formed by laminating an n type epitaxial layer on an n⁺ type silicon substrate 1. A mask (not illustrated here) formed by laminating, for example, an oxide film/polysilicon film/nitride film in this order is then etched at predetermined regions and an oxide film is grown in this opening to thus form a LOCOS oxide film 4.

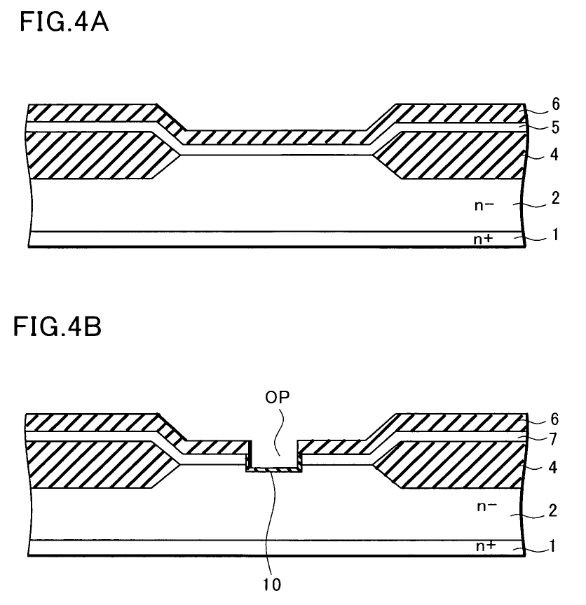

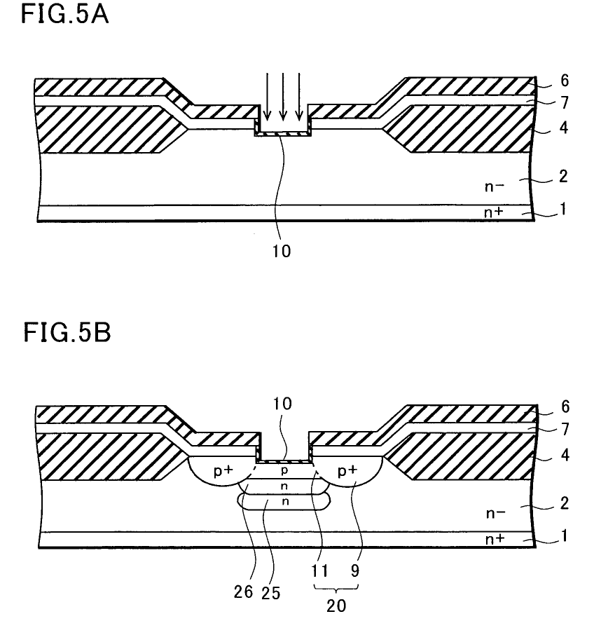

A second process of forming an opposite conductivity type base region on a surface of the collector region, a first one conductivity type impurity layer and a second one conductivity type impurity layer at a lower portion of the base region is next described with reference to FIG. 4 and FIG. 5.

First, a base extraction electrode functioning as a base diffusion source is formed on a surface of the collector region 2. In more detail, a polysilicon layer 5 is deposited on the entire surface and p type impurities are ion implanted. The acceleration energy at this time is around 40 KeV and the ion implantation dose is about 5E15 cm⁻². An insulating film such as a TEOS film 6, etc. is also formed as shown in FIG. 4A.

An opening OP is provided in a part where the emitter region is to be formed and a polysilicon layer 5 is patterned in a predetermined shape. The opening OP is thus formed by etching the polysilicon layer 5 and the TEOS film 6 which are exposed from the resist film. Next, the resist film is removed and thus a base extraction electrode 7 also functioning as a base diffusion source is formed. Then, an insulating film 10 is formed in the opening OP for protecting the bottom of the opening OP and for insulating the emitter and the base from one another as shown in FIG. 4B.

Next, as shown in FIG. 5, a base region 20, a first SIC layer 25 and a second SIC layer 26 are formed. First one conductivity type impurities (for instance phosphorous) are ion implanted (SIC) in the bottom of the opening OP at an acceleration energy of 300 KeV in a dose of 2E13 cm⁻². Also, second one conductivity type impurities (for instance arsenic As) are ion implanted (SIC) at an acceleration energy of 300 KeV in a dose of 2E12 cm⁻². Finally, opposite conductivity type impurities (for instance boron fluoride) are ion implanted at an acceleration energy of 16 KeV in a dose of 3E13 cm⁻² to form a genuine base region. (Refer to FIG. 5A)

Next, a heat treatment is carried out for a short period of time (1000° C. for about 5 seconds) by an RTA method. An outside base region 9 is thus formed by diffusing p type impurities from the base diffusion source 7 into the collector region 2. Simultaneously, boron fluoride is diffused in the collector region 2 to form the genuine base region 11 which is in contact with the outside base region 9 and which thus forms the base region 20.

The first SIC layer 25 and the second SIC layer 26 are formed right below the genuine base region 11 by simultaneously diffusing phosphorus and arsenic. The depth of the first SIC layer 25 differs from the depth of the second SIC layer 26 due to a difference in the diffusion coefficient.

In more detail, here, the first SIC layer 25 at a deep position, the second SIC layer 26 provided on the first SIC layer 25 and the genuine base region 11 formed on the second SIC layer 26 can be formed simultaneously in one heat treatment process. (Refer to FIG. 5B)

The second SIC layer 26 contacts the genuine base region 11 so that a lower edge of the genuine base region 11 can be cut in order to obtain the genuine base region 11 having a predetermined width.

The first SIC layer 25 contacts the second SIC layer 26 and it is preferably formed at a deep position from the substrate surface. The first SIC layer 25 and the second SIC layer 26 right below the genuine base region 11 are formed stepwise by increasing the impurity concentration of the first SIC layer 25 to be higher than that of the second SIC layer 26. The genuine base region 11 and the emitter region to be formed in a subsequent process are regions having a minute width (depth). Since too many heat treatments negatively influence the impurity concentration profile of these regions, it is preferable that two SIC layers are formed in one heat treatment process as described in the present embodiment.

A third process of forming a one conductivity type emitter region in the base region is next described with reference to FIG. 6.

First, in case the insulating film 10 is thin against the breakdown voltage between the emitter and base, an additional insulating film (not illustrated here) is formed on the insulating film 10. Then, a sidewall is formed on inner walls of the opening OP in order to form an emitter region by self alignment. In more detail, a polysilicon layer is deposited on the entire surface and etch back is carried out so as to form a sidewall 13 on inner walls of the opening OP. (See FIG. 6A)

Further, because an emitter region is formed on the surface of the genuine base region 11, the insulating film 10 on the genuine base region 11 is removed by wet etching at the bottom of the opening OP to thus form an emitter contact EC exposing the genuine base region 11. In the next step, an emitter diffusion source is formed by depositing a polysilicon layer on the entire surface and implanting n type impurities so that the inside of the opening OP is covered with the polysilicon layer. The polysilicon layer is then patterned so that the opening OP and a predetermined shape necessary for wiring are left. Thus, an emitter extraction electrode 15 covering the inside of the opening OP and functioning as an emitter diffusion source is formed. The emitter extraction electrode 15 contacts the genuine base region 11 via the emitter contact EC and a part thereof is also provided on the TEOS film 6 at the periphery of the opening OP. (See FIG. 6B)

Then, n type impurities are diffused from the emitter diffusion source (the emitter extraction electrode) 15 into a surface of the genuine base region 11 to form an emitter region 16. (See FIG. 6C)

An insulating film 17 comprising a BPSG film and a SOG film, etc. is then formed on the LOCOS oxide film 4 and a through hole TH is then opened in the insulating film 17 and the TEOS film 6. Also, a new resist film is formed and the through hole TH is opened in the insulating film 17 on the emitter extraction electrode 15. After forming a metal layer, it is patterned in predetermined shapes to form the base electrode 18 which is in contact with the base extraction electrode 7. An emitter electrode 19 which is in contact with the emitter extraction electrode 15 is further provided and a collector electrode (not shown here) electrically contacting the collector region 2 is also formed to obtain the final structure shown in FIG. 1B. Outside of the operation region 21, an emitter pad electrode 23 in contact with the emitter electrode 19 and a base pad electrode 22 in contact with the base electrode 18 are also formed. (See FIG. 1A)

A second embodiment of the present invention is next described with reference to FIG. 7 thru FIG. 11.

In a second embodiment of the present invention, a groove 8 is provided on a genuine base region 11 in order to reduce resistance of an outside base region and improve high frequency characteristic.

FIG. 7 shows a cross-sectional view taken along line A-A of FIG. 1A. Elements which are identical to those described with reference to the first embodiment are represented by the same numerical symbol and description of overlapping places is hereby omitted.

As shown in FIG. 7, a groove 8 is provided at a depth of about 0.1 um to 0.2 um from a lower edge of a base extraction electrode 7 between outside base regions 9 and a side wall thereof contacts a vicinity of a surface of the outside base regions 9. By this contact of the side wall of the groove 8 and a vicinity of a surface of the outside base regions 9, the progression of substrate horizontal diffusion (transversal diffusion) in the vicinity of a surface of the outside base regions 9 is suppressed.

In more detail, the outside base region 9 which contacts the genuine base region 11 is provided by diffusion at a depth of about 0.4 um to 0.5 um from the surface. The genuine base region 11 is provided on a surface of a collector region 2 at the bottom of the groove 8 and a surface thereof is positioned lower than a surface of the outside base region 9.

A first SIC layer 25 and a second SIC layer 26 are provided at a lower portion of the genuine base region 11. In this embodiment, the genuine base region 11 is positioned deeper as the depth of the groove 8 in comparison with the first embodiment. In other words, the first SIC layer 25 and the second SIC layer 26 can both be positioned deeper than compared to the first embodiment.

A first conductivity type emitter region 16 is provided on a surface of the genuine base region 11 at the bottom of the groove 8.

The base extraction electrode 7 contacts a base electrode 18 via a through hole TH provided in a TEOS film 6 and an interlayer dielectric film 17 at a surface of a LOCOS oxide film 4. In the present embodiment, since the transversal diffusion is suppressed by the grove 8, the impurity concentration in the base extraction electrode 7 can be set to be around 2E20 to 3E20 cm⁻³ so that the impurity concentration of the outside base region 9 can be increased.

An emitter extraction electrode 15 is provided to cover the inside of the groove 8 and a lower edge thereof is positioned lower than a joint surface of the base extraction electrode 7 and the outside base region 9.

A manufacturing method of a semiconductor device according to a second embodiment of the invention is next described with reference to FIG. 8 thru FIG. 11.

A first process of forming a one conductivity type collector region on a semiconductor substrate is described with reference to FIG. 8.

A collector region 2 is formed by laminating an n⁻ type epitaxial layer, for example, on an n⁺ type silicon substrate 1. A mask (not shown here) is formed by laminating an oxide film/polysilicon film/nitride film in this order and then etching at a predetermined region. Then, a LOCOS oxide film 4 is formed by growing an oxide film in the opening.

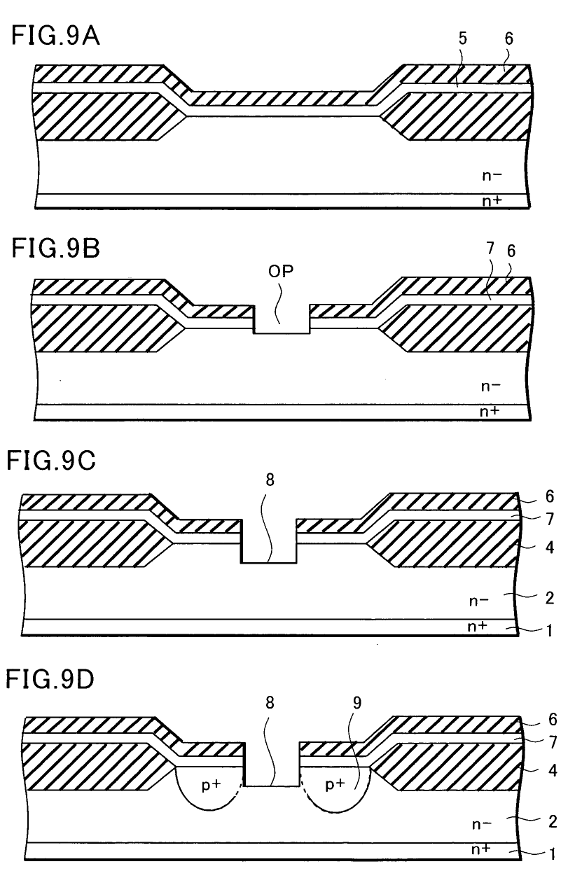

A second process of forming a groove in the surface of the collector region between regions to become outside base regions is hereinafter described with reference to FIG. 9.

First, a base extraction electrode to become a base diffusion source is formed on a surface of the collector region 2. In more detail, a polysilicon layer 5 is deposited on the entire surface and p type impurities are ion implanted therein. The acceleration energy at this time is about 40 KeV and the ion implantation dose is about 1.0E16 cm⁻², which corresponds to double the conventional dose. Further, an insulating film such as a TEOS film 6, etc. is also deposited (See FIG. 9A)

Next, since a predetermined emitter region is created by forming an opening and the polysilicon layer 5 is patterned in a predetermined shape, a mask made of a resist is provided so as to form an opening OP by etching and removing the exposed polysilicon layer 5 and TEOS film 6. Next, the resist film PR is removed. A base extraction electrode 7 also functioning as a base diffusion source is thus formed thereby (See FIG. 9B).

Next, the collector region 2 exposed from the opening OP is etched about 0.1 um to 0.2 um. A groove 8 is thus formed by removing the surface of the collector region 2 between base extraction electrodes 7 exposed from the opening OP. (See FIG. 9C)

P type impurities inside the base diffusion source 7 are diffused in the surface of the collector region 2 in a heat treatment process at 900° C. for 30 minutes to form an outside base region 9. As described above, high concentration impurities are doped in the base diffusion source 7 to form a deep outside base region 9. At this time, the transversal diffusion progresses, but when reaching sidewalls of the groove 8 in a vicinity of a surface having the highest impurity concentration and favoring progression of transversal diffusion, progression thereof is suppressed. In other words, after reaching sidewalls of the groove 8, diffusion progresses in a depth direction of the substrate.

Accordingly, the outside base region 9 contacting sidewalls of the groove 8 and having a diffusion depth of about 0.4 um to 0.5 um from the surface is formed. In this state, the outside base region 9 is exposed from sidewalls of the groove 8.

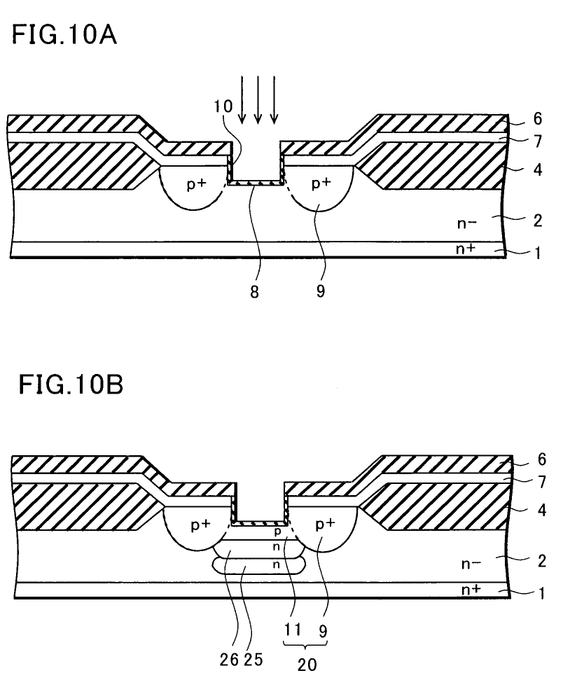

In the first embodiment, an outside base region is formed simultaneously with diffusion of the genuine base region in a short heat treatment process by an RTA method in order to suppress diffusion. However, according to the present embodiment, even by setting a very deep diffusion region by high impurity concentration, a low resistance outside base region 9 can be obtained while little influence is exerted on the genuine base region. (See FIG. 9D) A third process of ion implanting first one conductivity type impurities, second one conductivity type impurities and opposite conductivity type impurities between outside base regions is hereinafter described with reference to FIG. 10.

First, an insulating film 10 is formed for protection of the surface of the genuine base region and for insulating between the emitter and base after which first one conductivity type impurities (for instance phosphorus) are ion implanted (SIC) in the bottom of the groove 8 and further, second one conductivity type impurities (for instance arsenic) are ion implanted (SIC). Finally, opposite conductivity type impurities (for instance boron fluoride) are ion implanted to form a genuine base region. (See FIG. 10A)

Next, heat treatment is carried out for a short period of time (1000° C. for about 5 seconds) by an RTA method to diffuse opposite conductivity type impurities in the collector region 2 and thus form a genuine base region 11. The genuine base region 11 contacts the outside base region 9 and forms a base region 20. With this configuration, even in case of a transversal diffusion of the outside base region 9 at a lower position than the groove 8, the influence exerted on the genuine base region 11 is very little due to the fact that the impurity concentration is low.

Also, first and second one conductivity type impurities are simultaneously diffused to form a first SIC layer 25 and a second SIC layer 26 on a surface thereof, respectively. These two SIC layers comprise impurities having a different diffusion coefficient and can be formed simultaneously in one heat treatment process. Accordingly, the genuine base region 11 can maintain a predetermined impurity concentration profile without being influenced in any way by the outside base region 9 (See FIG. 10B).

A fourth process of forming a one conductivity type emitter region in a genuine base region is next described with reference to FIG. 11.

First, in case the insulating film 10 is thin against the breakdown voltage between the emitter and the base, an additional insulating film (not illustrated here) is formed on the insulating film 10. Then, a sidewall is formed on inner walls of the groove 8 in order to form an emitter region by self alignment. In more detail, a polysilicon layer is deposited on the entire surface and etch back is carried out so as to form a sidewall 13 on inner walls of the groove 8. (See FIG. 11A)

Further, because an emitter region is formed on the surface of the genuine base region 11, the insulating film 10 on the genuine base region 11 is removed by wet etching at the bottom of the groove 8 to thus form an emitter contact EC exposing the genuine base region 11.

In the next step, a polysilicon layer is deposited on the entire surface and n type impurities are doped so that the inside of the groove 8 is covered with the polysilicon layer. The polysilicon layer is then patterned so that the groove 8 and a predetermined shape necessary for wiring are left. Thus, an emitter extraction electrode 15 covering the inside of the groove 8 and functioning as an emitter diffusion source is formed. The emitter extraction electrode 15 contacts the genuine base region 11 at the emitter contact EC and a portion thereof is also provided on the TEOS film 6 at a periphery of the groove 8. (See FIG. 11B)

Next, n type impurities are diffused from the emitter diffusion source 15 in the surface of the genuine base region 11 to form an emitter region 16. As described hereinbefore, the genuine base region 11 at the bottom of the groove 8 is formed by a predetermined impurity concentration profile so that a predetermined base width Wb is obtained by forming an emitter region 8. (See FIG. 11C)

An insulating film 17 comprising a BPSG film and a SOG film, etc. is then formed on the LOCOS oxide film 4 and a through hole TH is then opened in the insulating film 17 and the TEOS film 6. Also, a new resist film is formed and a through hole TH is opened in the insulating film 17 on the emitter extraction electrode 15. After forming a metal layer, it is patterned in a predetermined shape to form a base electrode 18 which is in contact with the base extraction electrode 7. An emitter electrode 19 which is in contact with the emitter extraction electrode 15 is further provided and a collector electrode (not shown here) electrically contacting the collector region 2 is also formed to obtain the final structure shown in FIG. 7. Outside of the operation region 21, an emitter pad electrode 23 in contact with the emitter electrode 19 and a base pad electrode 22 in contact with the base electrode 18 are also formed. (see FIG. 1A)

1. A semiconductor device comprising:
a collector region of a first conductivity type formed on a substrate;
a base region of a second conductivity type formed in a surface portion of the collector region;
an emitter region of the first conductivity type formed in a surface portion of the base region;
a first impurity layer of the first conductivity type that is formed in the collector region and under the base region; and
a second impurity layer of the first conductivity type that is formed in the collector region and between the first impurity layer and the base region.

2. The semiconductor device of claim 1, wherein the base region comprises a genuine base region and an outside base region in contact with the genuine base region, and the first and second impurity layers are disposed under the genuine base region.

3. The semiconductor device of claim 2, wherein the second impurity layer is in contact with the genuine base region and the first impurity layer.

4. The semiconductor of claim 1, wherein the first impurity layer has a higher impurity concentration than the second impurity layer.

5. The semiconductor device of claim 1, wherein the first impurity layer has a higher impurity concentration than the collector region.

6. The semiconductor device of claim 5, wherein impurities of the first impurity layer have a larger diffusion coefficient than impurities of the second impurity layer.

7. The semiconductor device of claim 2, wherein a groove is formed in the genuine base region so that impurity diffusion from the outside base region to the genuine base region is prevented by a sidewall of the groove.

8. A method of manufacturing a semiconductor device, comprising:
forming a collector region of a first conductivity type on a substrate;
forming a base region of a second conductivity type in a surface portion of the collector region, a first impurity layer of the first conductivity type in the collector region and under the base region and a second impurity layer of the first conductivity type in the collector region and between the base region and the first impurity layer; and
forming an emitter region of the first conductivity type in a surface portion of the base region.

9. The method of claim 8, wherein the first impurity layer is formed to have a higher impurity concentration than the second impurity layer.

10. The method of claim 8, wherein the first impurity layer is formed to have a higher impurity concentration than the collector region.

12. The method of claim 8, wherein the base region, the first impurity layer and the second impurity layer are formed simultaneously in one heat treatment.

13. The method of claim 8, wherein the forming of the base region comprises forming a groove in the collector region, forming a genuine base region under the groove and forming a outside base region along a side wall of the groove.

14. A method of manufacturing a semiconductor device, comprising:
forming a collector region of a first conductivity type on a substrate;
forming two outside base regions of a second conductivity type in a surface portion of the collector region;
ion implanting between the two outside base regions first impurities of the first conductivity type, second impurities of the first conductivity type and impurities of the second conductivity type;
forming a genuine base region of the second conductivity type between the two outside base regions, a first impurity layer of the first conductivity type under the genuine base region and a second impurity layer of the first conductivity type between the genuine base region and the first impurity layer; and
forming an emitter region of the first conductivity type in a surface portion of the genuine base region.

15. The method of claim 14, wherein the first impurity layer has a higher impurity concentration than the second impurity layer.

16. The method of claim 14, wherein the first impurity layer has a higher impurity concentration than the collector region.

17. The method of claim 14, wherein the genuine base region, the first impurity layer and the second impurity layer are formed simultaneously in one heat treatment.

18. The method of claim 14, wherein the forming of the two outside base region comprises forming a groove in the surface portion of the collector region and diffusing impurities after the formation of the groove.
